(19) United States
(12) Patent Application Publication
(10) Pub. No.: US 2026/0319043 A1
(43) Pub. Date: Oct. 15, 2026

(54) SYSTEMS AND METHODS FOR RADIO FREQUENCY (RF) BASED SPATIAL ENCODING IN MAGNETIC RESONANCE IMAGING USING FREQUENCY-MODULATED RF PULSES

(71) Applicant: Regents of the University of Minnesota, Minneapolis, MN (US)

(72) Inventors: Michael GARWOOD, Minneapolis, MN (US); Parker John BRESNAHAN JENKINS, Minneapolis, MN (US)

(21) Appl. No.: 19/485,742

(22) PCT Filed: May 20, 2024
(86) PCT No.: PCT/US2024/030263

§ 371 Date: Nov. 19, 2025

Related U.S. Application Data
(60) Provisional application No. 63/503,282, filed on May 19, 2023.

(51) Int. Cl. G01R 33/483; G01R 33/34

(52) U.S. Cl. CPC G01R 33/4831; G01R 33/34046

(57) ABSTRACT

Radio frequency (“RF”) gradient based magnetic resonance imaging (“MRI”) is provided by establishing a gradient in the RF transmit (Bi) field using frequency-modulated RF pulses that are achieved by two or more gradient sets. A phase can be imparted to the magnetic resonance signals, where the phase can comprise of the superposition of the phase imparted by each RF pulse. The parameters of the RF pulses or gradient sets can be chosen to optimize the phase accrual over the imaging volume based on a target phase pattern. The RF pulses can be modified to modify the phase to provide phase encoding of the acquired data. The magnetic resonance signals measured can be reconstructed by standard reconstructions or model-based reconstructions to provide magnetic resonance images without the use of costly and large Bo gradient sets.

### CROSS-REFERENCE TO RELATED APPLICATIONS

This application is based on, claims priority to, and incorporates herein by reference for all purposes, U.S. Provisional Patent Application No. 63/503,282 filed on May 19, 2023.

### STATEMENT REGARDING FEDERALLY SPONSORED RESEARCH

This invention was made with government support under EB025153 and EB027061 awarded by the National Institutes of Health. The government has certain rights in the invention.

### BACKGROUND

Magnetic resonance imaging (“MRI”) permits robust, high-resolution imaging with tunable image contrast that is free of ionizing radiation, thereby making it an indispensable tool in clinical medicine and biomedical research. However, the financial burden of purchasing and maintaining such a technology is a considerable drawback that limits MRI access to mostly wealthy institutions in developed countries. In recent years, researchers have focused on developing lower cost and/or portable MRI systems to address these challenges. Most of these investigations have focused on redesigning various components of the MRI system. Other approaches have targeted the stringent requirements of the static field B₀ gradient systems. Conventional linear B₀-gradient coils consume precious space in the magnet bore, require significant electrical power and water cooling to operate, require maintenance, and produce loud acoustic noise, which is a common complaint of patients and potentially damaging to their hearing. Elimination of the B₀ gradient system would significantly reduce the infrastructure needs and financial burden of MRI, while simultaneously permitting silent MRI.

One approach for spatial encoding without magnetic field gradients is referred to as transmit array spatial encoding (TRASE). TRASE utilizes specialized radio frequency (RF) coils with complex pulsing patterns to generate a coil-dependent phase profile over the field-of-view. This coil-dependent phase profile provides spatial encoding of magnetic resonance signals. TRASE is limited, however, by its sensitivity to resonance offset.

Another approach for eliminating the need of the B₀ gradient system is the use of an RF coil or RF parallel transmit (pTx) array to produce spatially varying phase over the imaging volume using frequency-modulated Rabi encoded echoes (FREE). In general, FREE techniques accomplish spatial encoding of magnetic resonance signals using frequency-modulated RF pulses (e.g., adiabatic full passage (AFP) pulses, or the like) that are transmitted with a spatially varying RF field amplitude. Advantageously, FREE techniques are minimally affected by resonance offset.

Standard FREE techniques generally produce nonlinear phase, which can create spatially variable resolution and cause geometric distortions during Fourier reconstruction. The phase profile generated by standard FREE techniques may also not be analogous to B₀ gradients because the RF gradient magnitude cannot approach zero and maintain adiabaticity with conventional techniques.

### SUMMARY OF THE DISCLOSURE

The present disclosure addresses the aforementioned drawbacks by providing a method for magnetic resonance imaging (MRI), in which the magnetic resonance data can be spatially encoded by a superposition of at least a first and second radiofrequency (RF)-induced phase pattern. To generate the first RF-induced phase pattern, a first RF pulse can be applied using a first RF gradient set of an RF coil assembly of the MRI system. To generate the second RF-induced phase pattern, a second RF pulse can be applied using a second RF gradient set of the RF coil assembly of the MRI system.

It is another aspect of the present disclosure to provide a method for MRI, in which magnetic resonance data are acquired from a subject using an MRI system to generate a pulse sequence. The pulse sequence can include an RF excitation pulse, followed by a first RF pulse that is generated by a first RF gradient set, followed by a second RF pulse generated by a second RF gradient set. The magnetic resonance data can be acquired with the MRI system by sampling the magnetic resonance signals formed in response to the RF excitation pulses. The magnetic resonance signals will have a phase imparted that includes the superposition of a first phase component whose value is dependent on the first RF gradient set and a second phase component whose value is dependent on the second RF gradient set. Images can be reconstructed from the acquired magnetic resonance data.

It is still another aspect of the present disclosure to provide a method for MRI in which magnetic resonance data can be acquired from a subject using an MRI system to generate a pulse sequence. The pulse sequence can generate a plurality of RF gradients using a plurality of RF pulses. A superposition of the RF gradients can provide spatial encoding of the magnetic resonance data, which can be used to reconstruct an image.

The foregoing and other aspects and advantages of the present disclosure will appear from the following description. In the description, reference is made to the accompanying drawings that form a part hereof, and in which there is shown by way of illustration a preferred embodiment. This embodiment does not necessarily represent the full scope of the invention, however, and reference is therefore made to the claims and herein for interpreting the scope of the invention.

### BRIEF DESCRIPTION OF THE DRAWINGS

FIG. 1A is a pulse sequence diagram for a standard frequency-modulated Rabi encoded echoes (“FREE”) technique, which imparts phase onto an imaging volume using a single gradient set to generate a radio frequency (“RF”) gradient using frequency-modulated RF pulses.

FIG. 1B is a schematic illustration of an example coil setup for an imaging volume using the pulse sequence of FIG. 1A and the resulting phase across the imaging volume.

FIG. 2A is a pulse sequence diagram for a sequential gradient superposition (“SGS”)-FREE technique, which imparts phase onto an imaging volume using multiple gradient sets to generate the superposition of radio frequency (“RF”) gradients using frequency-modulated RF pulses.

FIG. 2B is a schematic illustration of an example coil setup for an imaging volume using the pulse sequence of FIG. 2A and the resulting superposition of phase across the imaging volume.

FIG. 3A is a pulse sequence diagram of the SGS-FREE technique applied for 2-dimensional phase encoding.

FIG. 3B is an imaging setup that may be used with the pulse sequence of FIG. 3A.

FIG. 4A is a graph of the positions in k-space across the imaging volume using standard FREE technique.

FIG. 4B is a graph showing the positions in k-space across the imaging volume using SGS-FREE for comparison with that of FIG. 4A to show the difference between the phase encoding achieved using standard FREE and SGS-FREE approaches for an experimental example.

FIG. 5 shows an example imaging setup that may be used to achieve the SGS-FREE techniques in accordance with some aspects of the present disclosure.

FIG. 6A shows a Bit profile of an 8-channel bird cage coil use for simulation in accordance with the present disclosure.

FIG. 6B shows example gradients in the x and y dimensions that may be achieved using the methods described in the present disclosure to provide 2D spatial encoding.

FIG. 6C shows a simulated example of images reconstructed using magnetic resonance data acquired using an SGS-FREE technique.

FIG. 7A shows an example of a multi-echo SGS-FREE pulse sequence in accordance with some aspects of the present disclosure.

FIG. 7B shows an example of a k-space trajectory achieved using the SGS-FREE pulse sequence of FIG. 7A.

FIG. 8 shows an example flowchart setting forth the steps of an example method for magnetic resonance imaging using an SGS-FREE technique as described in some embodiments of the present disclosure.

FIG. 9 is a block diagram of an example magnetic resonance imaging (“MRI”) system, which may be implemented for some embodiments of the present disclosure.

FIG. 10 is a block diagram of an example model-based image reconstruction system that can implement the methods described in some embodiments of the present disclosure.

FIG. 11 is a block diagram of example components that can implement the system of FIG. 10.

### DETAILED DESCRIPTION

Described herein are systems and methods for radio frequency (“RF”) gradient based magnetic resonance imaging (“MRI”). In particular, a gradient is established by the superposition of two or more B₁ RF fields to enable B₁-encoded pulse sequences, such as B₁-encoded spin-echo pulse sequences. Each of the B₁ fields can be established using two or more individual RF coils separated in space. The B₁ fields may also be produced by one or more RF coil arrays capable of parallel transmission (pTx) mode. The coils may be used to generate RF pulses (e.g., frequency-modulated, amplitude-modulated, composite, or other RF pulses capable of producing a spatially varying phase) that generate RF-induced phase patterns that may be spatially varying. The plurality of phase patterns can create a superposition of phase patterns, which can spatially encode the magnetic resonance signal. As a non-limiting example, the B₁-field gradient can be established using a sequential gradient superposition frequency-modulated Rabi encoded echoes (“SGS-FREE”) technique. In some embodiments, spatial models may be used to design the RF pulses to achieve a target phase pattern (e.g., linear) over the imaging volume. In some embodiments, a model-based image reconstruction framework can be implemented to reconstruct images from data acquired or otherwise encoded using the SGS-FREE techniques described in the present disclosure.

Advantageously, the systems and methods described in the present disclosure address the problems of the high-cost and low-accessibility of conventional MRI and can achieve an RF-based gradient, or phase pattern, analogous to the standard B₀ field gradient. In general, the systems and methods described in the present disclosure allow for spatial encoding, such as phase-encoding, based on a superposition of B₁-field gradients rather than using gradient coils to establish a magnetic field gradient in the main magnetic field, B₀, of the MRI scanner. Advantageously, the SGS-FREE technique described in the present disclosure can be adapted for used with any suitable pulse sequence, including those based on spin echoes, gradient echoes, or other such principles.

Phase-encoding is used for spatial encoding in nearly all MRI techniques. The systems and methods described in the present disclosure allow for linear or other controllable spatially varying phase patterns that allow for phase-encoding using only RF-coils, unlike current methods for conventional and portable MRI, which rely on hardware-specific gradient coils. Advantageously, the SGS-FREE technique described in the present disclosure allows for the removal of gradient coils, which opens the possibility of spatially encoding magnetic resonance data without gradient coils. Removing the need for gradient coils can significantly reduce cost in development and up-keeping of MRI systems.

With the SGS-FREE techniques described in the present disclosure, MRI systems can be more widely distributed. Advantageously, the systems and methods can be implemented with any field strength, including low-field (e.g., 0.2 T to 1.5 T) MRI systems, and/or portable MRI systems. In addition, the SGS-FREE techniques described in the present disclosure can facilitate silent MRI, since the SGS-FREE techniques allow for imaging without gradient coils, which are the components that create significant noise in conventional MRI. Noiseless MRI is advantageous for pediatric imaging and the general population.

As noted above, the systems and methods described in the present disclosure allow for spatially encoding magnetic resonance signals using a two or more spatially dependent RF fields, which can achieve a nearly linear or other target field without the use of the B₀-gradient coils conventionally used in MRI.

Previous RF imaging (“RFI”) techniques have attempted a similar goal but have had limited success for various reasons. In particular, rotating frame zeugmatography and other early RFI approaches are limited by their sensitivity to resonance offset, Δω=ω₀−ω_{RF}, where ω₀ is the Larmor frequency and ω_{RF} is the B₁ carrier frequency. With these methods, spatial information is encoded by evolving spins about an effective field, B_{eff},

B_{eff}=B₁\hat{x}+(Δω/γ)\hat{z}
in the rotating frame (x′, y′, z′), where Y is the gyromagnetic ratio. Transmit Array Spatial Encoding (“TRASE”), a more recent approach, faces a similar issue and requires specialized coils with complex pulsing patterns. Another approach, Bloch-Siegert shift encoding, has demonstrated promising results, but it requires pulses with high power to add phase shifts from off-resonant pulses, while still being susceptible to resonance-offset effects.

Another RFI technique may include using RF pulses to produce a spatially varying transverse magnetization. This can be achieved using B₁-dependent RF pulses that produce transverse magnetization with a phase that varies based on the amplitude of the RF pulse. For example, the transverse phase may be proportional or nearly proportional to the amplitude of the B₁ field. As one non-limiting example, such B₁-dependent phase can be achieved using frequency-modulated (“FM”) pulses. In some practical implementations, an FM RF pulse may be realized by using phase modulation with the MRI system hardware. For example, with digitized electronics, it can be easier to practically implement a phase modulation in steps that effectively result in the excited spins seeing a sweeping RF Field. The FREE techniques have overcome many of the challenges of these previous RFI techniques by using a frequency-modulated RFI method that accomplishes spatial encoding using adiabatic full-passage (“AFP”) pulses (e.g., hyperbolic secant (“HS”) pulses, chirp pulses), in spin-echo or other pulse sequences. As an example, 180-degree frequency swept RF pulses can be used, which advantageously don't require extra power (i.e., decreased power deposition) and are more efficient. In FREE, spatial information is encoded in the phase of the magnetization that results when AFPs are transmitted with a spatially varying RF field amplitude, B₁(r)

As another non-limiting example, composite RF pulses can be used to impart a B₁-dependent phase on the transverse magnetization. Such composite pulses can achieve an effective frequency modulation by stringing together several constant RF pulses (e.g., square pulses) while varying the phase of each individual RF pulse. Composite pulses can advantageously be performed using simpler hardware that is not required to produce a true frequency-modulated or phase-modulated RF pulse. In this way, while not truly adiabatic, composite pulses can be used to achieve spatial encoding.

As yet another non-limiting example, amplitude-modulated (“AM”) RF pulses can also be used to impart a B₁-dependent phase on the transverse magnetization. For instance, an AM RF pulse can be used to create a transverse phase that varies with the RF amplitude. This can be achieved when the AM RF pulse creates two counter rotating fields in the rotating frame, which collectively generate the transverse phase.

When using a frequency-modulated AFP as the refocusing pulse in a spin-echo sequence, the magnetization is left with a phase that depends on the B₁(r,t) function used. This B₁-dependent phase factor is additive to the Δω-dependent quadratic phase that results from the time dependence of the FM sweep. The B₁ dependence of the resulting magnetization phase is utilized to accomplish B₁-dependent phase encoding.

As a non-limiting example, the application of two AFP pulses with identical time-bandwidth product, R, in a double spin-echo sequence leads to refocused magnetization, removing all B₀- and B₁-dependent phase factors. With AFP pulses, the bandwidth can be held fixed when increasing the pulse duration by scaling the phase modulation proportionately. A relevant variable for controlling this process is the time-bandwidth product, R, which is the unitless product of the AFP pulse length T p and its bandwidth, BW. Application of two AFPs with differing time-bandwidth product leads to residual B₁-dependent phase, with some dependence on Δω. For instance, the R-value (i.e., time-bandwidth product) of the generated pulse patterns can be increased by increasing the pulse duration, while holding the pulse's bandwidth constant. In FREE, this B₁-dependent phase is exploited, in conjunction with a B₁-coil map, to perform phase encoding with AFPs in a double spin-echo sequence.

When executed adiabatically, AFPs perform a slow sweeping of \vec{B}_{eff}(t), such that the magnetization vector remains approximately collinear with \vec{B}_{ff}(t), provided the spin has a Larmor frequency somewhere in the range of the frequency sweep. AFP pulses can be described in terms of their amplitude- and frequency-modulated functions, ω₁=γB₁(t) and ω_{RF}(t) both in units of rad/s. Of note, ω₁ can be referred to as the Rabi frequency.

Hyperbolic secant (e.g., “HSn”) pulses are one non-limiting example class of AFP pulses that are capable of delivering uniform inversion profiles across large bandwidths. However, other pulse shapes may be used. For an HS1 pulse, the AM and FM functions can be written as

ω₁(τ)=ω₁^{max}sech(βτ)

ω_{RF}(τ)=ω_{c}+Atanh(βτ)
where

$$τ = 2 t / {T}_{p} - 1 for 0 \leq t \leq {T}_{p} , {ω}_{1}^{max}$$

is the peak Rabi frequency that varies spatially in FREE, ω_{c} is the center frequency in the FM sweep, A is the frequency-sweep cutoff (e.g., 0.5 BW), and β is a unitless truncation factor. As a non-limiting example, β can be set such that sech⁻¹(β)=0.01, so the pulse terminates when the amplitude reaches 1% of its peak value. In some implementations, frequency modulation can be implemented through a phase-modulated (“PM”) function, which is related to the FM function by

$$ϕ ( τ ) = {\int }_{0}^{τ} ( {ω}_{RF} ( {t}^{′} ) - {ω}_{c} ) {dt}^{′} .$$

When starting with transverse magnetization, the B₁-dependent phase accrued from an HS1 pulse is given by,

$${ϕ}_{H S} = \pm \frac{{T}_{p}}{2} {\int }_{- 1}^{1} \sqrt{{( {ω}_{1}^{max} )}^{2} {sech}^{2} ( β τ ) + {( Ω - A tanh ( β τ ) )}^{2}} d τ ;$$

$${ϕ}_{H S} = \pm \frac{{T}_{p}}{2} {\int }_{- 1}^{1} {ω}_{eff} ( τ , r ) d τ .$$

The variable Ω is used to represent any constant offset that occurs, for example, from chemical shift and/or B₀ inhomogeneity. When decomposing the phase into Ω- and

$${ω}_{1}^{max}$$

-components, the following is obtained,

$${ϕ}_{HS 1} ( Ω , {ω}_{1}^{max} ) = {ϕ}_{HS 1 , 1} ( Ω ) + {ϕ}_{HS 1 , 2} ( {ω}_{1}^{max} ) ;$$

$$where$$

$${ϕ}_{HS 1 , 1} ( Ω ) = \frac{A {T}_{p}}{β} ln ( \frac{1}{\sqrt{{A}^{2} - {Ω}^{2}}} ) - \frac{{T}_{p} Ω}{2 β} ln ( \frac{A + Ω}{A - Ω} ) ;$$

$${ϕ}_{HS 1 , 2} ( {ω}_{1}^{max} ) = A {T}_{p} ( \frac{1}{β} log ( {ω}_{1}^{max} ) - 1 ) + \frac{{T}_{p} \sqrt{{( {ω}_{1}^{max} )}^{2} - {A}^{2}}}{2 β} {tan}^{- 1} ( \frac{2 A \sqrt{{( {ω}_{1}^{max} )}^{2} - {A}^{2}}}{- 2 {A}^{2} + {( {ω}_{1}^{max} )}^{2}} ) .$$

By utilizing the

$${ω}_{1}^{max}$$

-dependence, an Kr con producing a spatially varying B₁ field can encode phase across the object. Such magnetization can be inverted in an adiabatic manner, which can advantageously provide insensitivity to field inhomogeneity.

While the previously described FREE technique can achieve spatial encoding without the use of costly and large B₀ gradient sets, the FREE technique can have limited application when the linearity of the phase accrual is limited. In these instances, it can be challenging to create conventional phase encoding (i.e., phase encoding in which fully sampled Fourier encoding requires the magnetization phase to vary linearly, such that the Nyquist criterion can be satisfied) when using the conventional FREE technique.

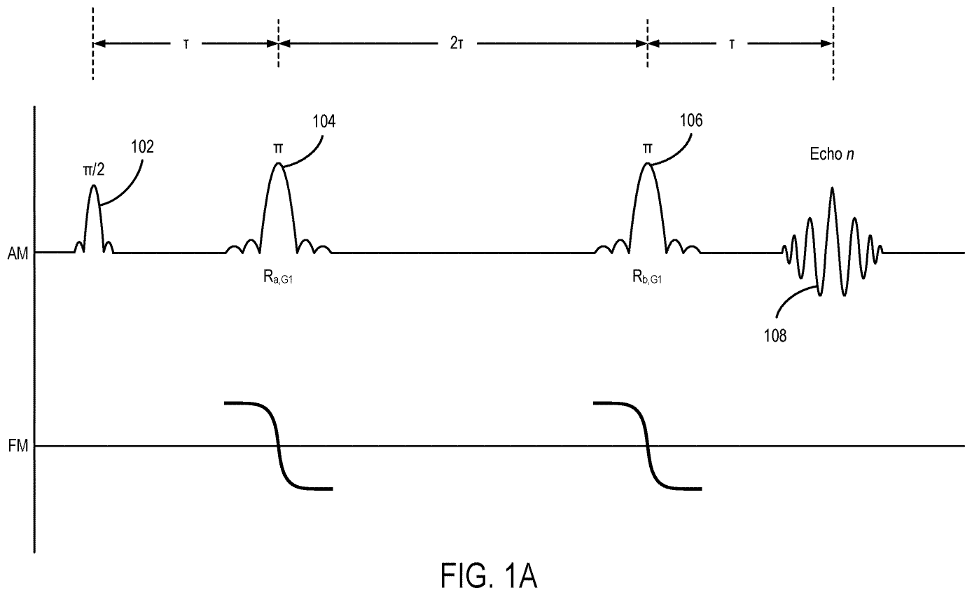

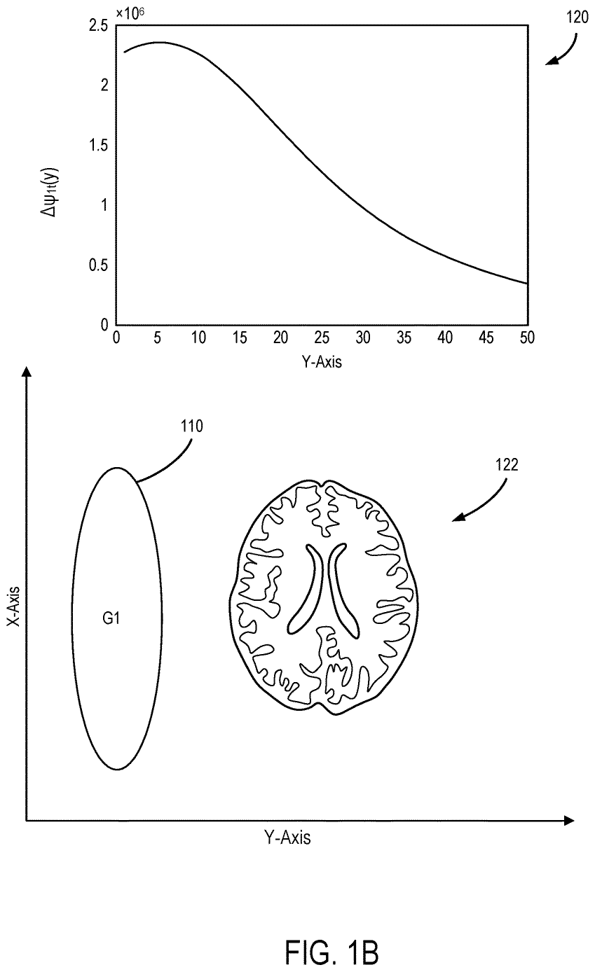

An example of the typical FREE technique is illustrated as a double spin-echo sequence in FIG. 1A. Standard FREE methods, employs frequency-modulated adiabatic RF pulses. Thus, the following example is based on such pulses. However, as previously described and as one of ordinary skill in the art would appreciate, other RF pulses can be used to achieve B₁-dependent phase of the transverse magnetization for FREE-based and SGS-FREE based methods, including composite RF pulses, AM RF pulses, and so on.

The pulse sequence begins with an excitation of transverse magnetization by an RF excitation pulse 102, such as a hard pulse. At a time t later, a first frequency-modulated (FM) adiabatic full passage (AFP) RF pulse A 104 (e.g., hyperbolic secant (“HS”) pulse, chirp pulse, etc.) is used to produce a 180° rotation of magnetization that has B₁⁺ dependent phase. At a time 2τ later a second RF AFP RF pulse B 106 (e.g., hyperbolic secant (“HS”) pulse, chirp pulse, etc.) is used to, once again, produce a 180° rotation of magnetization that has B₁⁺ dependent phase. The use of a double spin-echo sequence, or other suitable pulse sequence will negate the effect of B₀-inhomogeneity (accounted for by Ω), leaving only a linear dependence on

$${ω}_{1}^{max} .$$

If the RF gradient varies monotonically as a function of axis position (y), this is analogous to phase encoding with B₀ field gradients. Assuming strong adiabaticity, the spatially varying phase accrued by a single FM AFP RF pulse can be described as:

$$ψ ( y , t ) = {\int }_{0}^{t} {ω}_{eff} ( τ , y ) d τ ;$$

wherein t=[0 Tₚ], y=[0, Δr], and

$${ω}_{eff} ( y , t ) = \sqrt{{( {ω}_{1 gradient}^{max} ( y ) * AM ( t ) )}^{2} + {( A * FM ( t ) )}^{2}} .$$

T_{P} is the pulse duration, t is a dummy integration variable, t is time, y is a spatial distance, Δr is the spatial length of the RF gradient. AM(t) and FM(t) are the amplitude and frequency modulation functions of the AFP pulse. BW_{Ω} is the bandwidth of the pulse, A=BW_{Ω}/2 and

$${ω}_{1 gradient}^{max}$$

is the spatial peak RF gradient magnitude (=γB₁⁺).

Standard 1D phase-encoded (PE) FREE uses two AFP pulses with a single RF gradient to phase encode the object over a double spin echo (DSE) sequence. By modulating the time-bandwidth products (Rₐ and R_{b}, where R=BW_{Ω}T_{P}) between the two AFP pulses, one can control the degree of phase encoding (i.e., traverse k-space) achieved at echo 108 according to

$$Δψ ( y ) = \frac{( {T}_{p , b} - {T}_{p , a} )}{2} {\int }_{- 1}^{1} \sqrt{{( {ω}_{2 G}^{max} ( y ) * AM ( t ) )}^{2} + {( A * FM ( t ) )}^{2}} d τ ;$$

wherein T_{p,b} and T_{p,a} are the pulse duration of pulse B 106 and pulse A 104, respectively.

In this case, as illustrated by FIG. 1B, the FM RF pulses A 104 and B 106 are played out by a single RF coil 110. The disadvantage of this approach can be understood from FIG. 1B, which clearly shows that the phase accrual achieved Δψ(y) (e.g., 120) across an axis (e.g. y) is non-linear across the full imaging volume 122. Moreover, the single RF gradient system G1 does not fully mimic the behavior of the conventional B₀ gradient system as the phase accrual Δψ(y) is positive along the full imaging volume 122 as dictated by the adiabatic condition of the RF pulse.

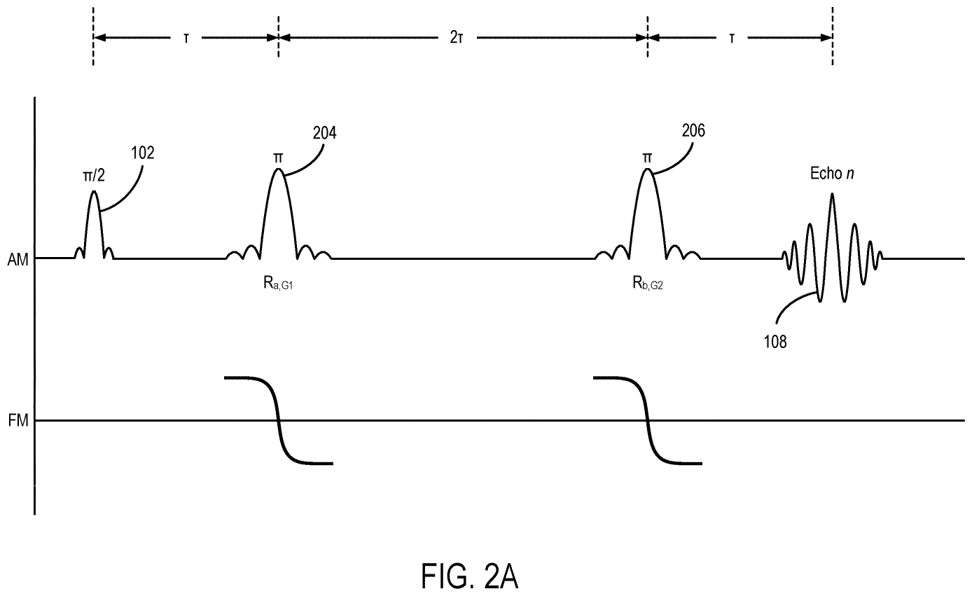

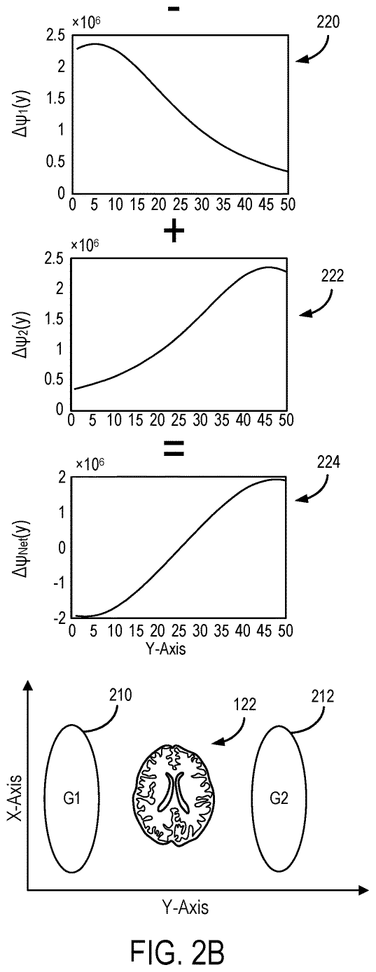

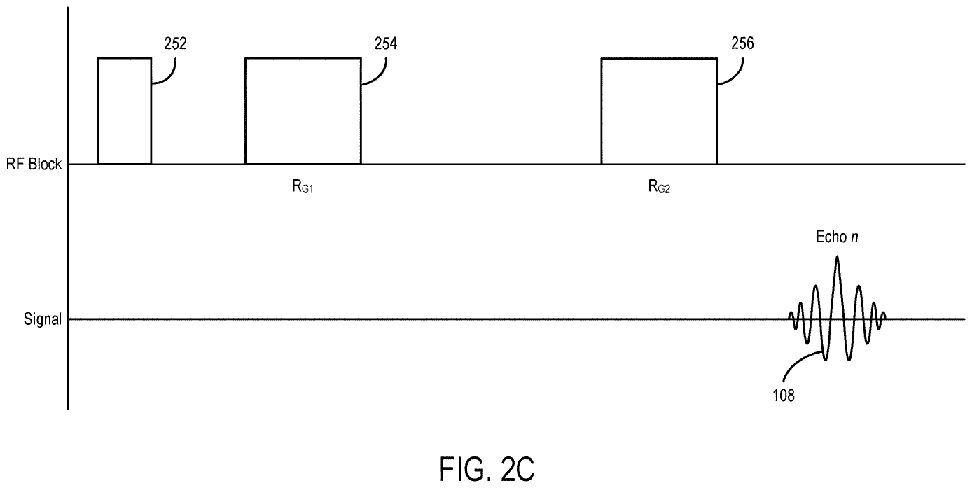

The present disclosure improves upon the conventional FREE technique by utilizing two or more RF gradient sets (e.g., G1 and G2) to generate sequential frequency-modulated RF pulses, which increases the degrees of freedom for RF gradient phase accrual. The gradient sets G1 and G2 can modulate the phase (e.g., along one spatial dimension, such as the y-direction or the x-direction; along two spatial dimensions, such as both the y-direction and the x-direction) during a pulse sequence (e.g., DSE sequence as shown in FIG. 2A) to produce phase patterns that superimpose together to provide spatial encoding of magnetic resonance signals. Advantageously, through the superposition of the gradient sets, a more uniform phase accrual can be achieved for spatial encoding (e.g., an approximately linear phase accrual, similar to those achievable with B0 gradient fields). As a non-limiting example, as illustrated in FIGS. 2A and 2B, a first gradient set G1 can include a single RF coil 210, and a second gradient set G2 can include a single RF coil 212. Alternatively, the gradient sets G1 and G2 can be defined by any subset of coil elements of an RF coil array capable of parallel transmission (pTx). The gradient sets G1 and G2 may include unique subsets of coil elements or equivalent coil elements, in which case G1 and G2 are distinguished based on the RF pulse parameters chosen, as will be described in further detail herein.

Referring now to FIGS. 2A and 2B, a non-limiting example is shown in which a pair of RF coils (210 and 212) is aligned along the y-direction (i.e., separated in space along the y-direction) to make up a first and second gradient set (G1 and G2). An example pulse sequence diagram is shown in FIG. 2A, in which a π/2 RF pulse 102 is used to excite the magnetization into the transverse plane. At a time t later, using an RF coil 210, gradient set G1 plays a FM RF pulse A 204 with time-bandwidth product R_{a,G1}, a duration T_{p,a}, and flip angle π. At a time 2τ later, using an RF coil 212, the second gradient set G2 plays a second RF pulse B 206 with time-bandwidth product R_{a,G1}, a duration T_{p,b}, and flip angle π. In some implementations the FM pulses 204 and 206 may be achieved in practice as phase-modulated RF pulses. As one non-limiting example, an FM pulse may be achieved by quadratically modulating the pulse phase. Thus, phase-modulated pulses may be referred to as FM pulses, and vice versa. In practice, FM pulses may be described by phase modulation variables. In some implementations, the FM pulses may also have an amplitude modulation described by amplitude modulation variables.

An echo 108 is formed at 4τ. At 4τ, the net phase accrual Δψ_{Net}(y) 224 will be defined by the superposition of the RF-induced phase accrual imposed by pulse A 204 of G1, i.e., Δψ₁(y) 220, and the phase accrual imposed by pulse B 206 by G2, i.e., Δψ₂(y) 222. Importantly, as illustrated in FIG. 2B, for example, the net phase accrual Δψ_{Net}(y) is nearly linear across the imaging volume 122 and crosses the axis Δψ_{Net}=0, thus mimicking the phase imposed by conventional B₀ gradient systems. However, other phase patterns may be achieved as well.

For example, if the RF pulses 204 and 206 are designed to have equal AM, FM, A, and Tₚ, (T_{p,a}=T_{p,b}) the net phase accrual can be described as:

$$Δψ ( y ) = \frac{{T}_{p}}{2} {\int }_{- 1}^{1} \sqrt{{( {ω}_{1 , G 2}^{max} ( y ) * AM ( t ) )}^{2} + {( A * FM ( t ) )}^{2}} - \sqrt{{( {ω}_{1 , G 1}^{max} ( y ) * AM ( t ) )}^{2} + {( A * FM ( t ) )}^{2}} d τ = {ψ}_{G 2} ( y ) - {ψ}_{G 1} ( y ) .$$

However, the RF pulses 204 and 206 are not limited by equal AM, FM, A, and Tₚ.

SGS-FREE can further be analyzed as an analytic field propagator in the first rotating frame in which the initial phase of each pulse, do, is assumed to be constant for both pulses and Δα=π is the total angle swept by the effective magnetic field, B_{eff}. The propagator can be described as:

$${U}_{π , G 1} {U}_{π , G 2} = [ \begin{matrix}\begin{matrix}cos ( {ψ}_{G 2} ( y ) - {ψ}_{G 1} ( y ) + \\ {β}_{G 1} ( y ) - {β}_{G 2} ( y ) )\end{matrix} & \begin{matrix}- sin ( {ψ}_{G 2} ( y ) - {ψ}_{G 1} ( y ) + \\ {β}_{G 1} ( y ) - {β}_{G 2} ( y ) )\end{matrix} & 0 \\ \begin{matrix}sin ( {ψ}_{G 2} ( y ) - {ψ}_{G 1} ( y ) + \\ {β}_{G 1} ( y ) - {β}_{G 2} ( y ) )\end{matrix} & \begin{matrix}cos ( {ψ}_{G 2} ( y ) - {ψ}_{G 1} ( y ) + \\ {β}_{G 1} ( y ) - {β}_{G 2} ( y ) )\end{matrix} & 0 \\ 0 & 0 & 1\end{matrix} ]$$

wherein β(y) is the spatially varying RF coil phase in the first rotating frame, and β_{G1}(y) and β_{G2}(y) are constrained so that it does not affect Δψ(y). Assuming adiabaticity, the net SGS-FREE solution is a z rotation of Ψ_{G1}−Ψ_{G2}. With sufficient |B₁⁺| across both RF gradient sets, the net transverse phase (Δψ(y)) accrual over the double spin echo is proportional as:

$$Δ ψ ( y ) ∝ \frac{{T}_{p}}{2} * {ω}_{1 SGS Net}^{max} ( y )$$

$$where {ω}_{1 SGS Net}^{max} ( y ) = \vert {ω}_{1 G 2}^{max} ( y ) \vert - \vert {ω}_{1 G 1}^{max} ( y ) \vert .$$

It should be understood that FIG. 2A and FIG. 2B provide an illustrative example of the present disclosure in which the SGS-FREE technique is implemented with a multi-shot double spin-echo sequence. In practice, the SGS-FREE methods can be used with any number of different pulse sequences, with various timings, flip angles, pulse shapes and durations, and other RF pulse parameters. Moreover, various RF coil assemblies can be employed, including any number of single RF coil elements or pTx RF coil arrays. Furthermore, additional RF gradient sets can be employed, the technique may be applied along a plurality of orthogonal or oblique axes, and the parameters of the RF pulses 204 and 206, etc. can be modified to achieve a variety of spatially varying phase patterns (e.g., 224) at each echo 108.

Furthermore, as previously described, the RF pulses (e.g., pulse A 204 and pulse B 206) may be replaced with other RF pulses that achieve a B₁-dependent phase. As a non-limiting example, FIG. 2C shows an example pulse sequence diagram that includes an excitation pulse block 252. For example, the excitation pulse block may include a 90° or π/2 excitation pulse performed with a slice selection gradient. The excitation pulse block 252 is followed by a first RF pulse block A 254 generated using a first gradient set (e.g., G1) and a second RF pulse block B 256 generated using a second gradient set (e.g., G2). The RF pulse blocks (e.g., 254 and 256) can be configured to produce a B₁-dependent phase of the transverse magnetization. Such phase may be spatially varying and sum together to provide a desired spatial encoding at the time of the echo 108. For example, the RF pulse blocks 254 and 256 may include non-adiabatic FM pulses. As another example, the RF pulses may include composite pulses made up of a train of shorter RF pulses (e.g., square amplitude), varying the phase or carrier frequency of each pulse. As another example, the RF pulses may include amplitude modulated pulses. These pulses can be configured to produce a B₁-dependent phase that can be used to provide spatial encoding.

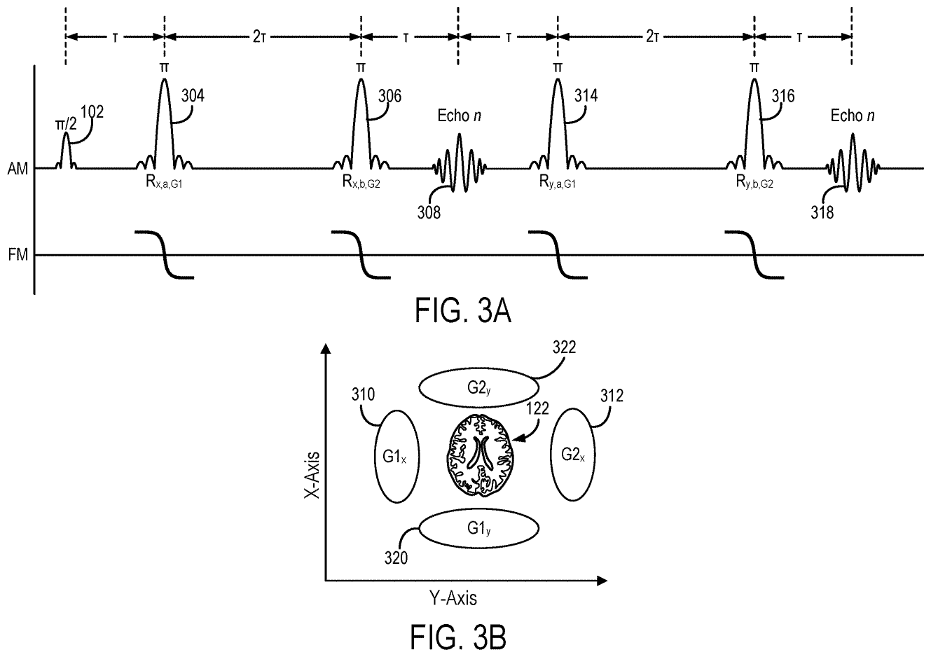

The 1D spatial encoding achieved by the pulse sequence illustrated in FIG. 2A and coil setup illustrated in FIG. 2B can be extended to achieve phase encoding along two dimensions. For example, FIGS. 3A and 3B illustrate a non-limiting example including two pairs of RF coils. The first pair is aligned along the y-direction, which provide two gradient sets (G1_{y} and G2_{y}). The second pair is aligned along the x-direction, which provide two more gradient sets (G1ₓ and G2ₓ). FIG. 3A illustrates an example of a pulse sequence that can be used in conjunction with the coil setup illustrated in FIG. 3B to spatially encode an imaging volume in 2 dimensions, such as x and y. The RF pulses Ay 304 with R_{y,a,G1} and By 306 with R_{y,b,G2} are achieved by the gradient sets G1_{y} and G2_{y}, which are defined by coils 310 and 312 that are spaced along the y-axis to create a phase gradient along y at echo 308. A phase gradient is also produced along x according to the RF pulses Ax 314 with R_{x,a,G1} 314 and Bx 316 with R_{x,b,G2} played by the gradient sets G1ₓ and G2ₓ, which are defined by coils 320 and 322 that are spaced along the x-axis. Thus, at echo 318 there is a gradient along both the x and y axes. Combinations of these pulses can be repeated with varying pulse durations, pulse shapes, or B₁ gradient field strengths to fully encode the x and y dimensions. 2D spatial encoding can similarly be achieved with other types of RF pulses (e.g., composite RF pulses, amplitude modulated RF pulses, and so forth) as previously described.

A relationship exists between the R-values of the FM RF pulses (e.g., 204, 206, 304, 306, 314, and 316) and the amount of phase encoding achieved. In practice, the R-values can readily be modified for each shot by modifying the pulse durations of the FM RF pulses. For a given field-of-view (“FOV”) and known B₁ gradient, the value of pulse durations that satisfies the Nyquist criterion can be determined. A k-space trajectory can thus be achieved by repeated incrementation of the pulse duration of the FM RF pulses with each shot, echo, or repetition. As another non-limiting example, the k-space trajectory can also be achieved by modifying the B₁ gradient strength or shape with each FM RF pulse.

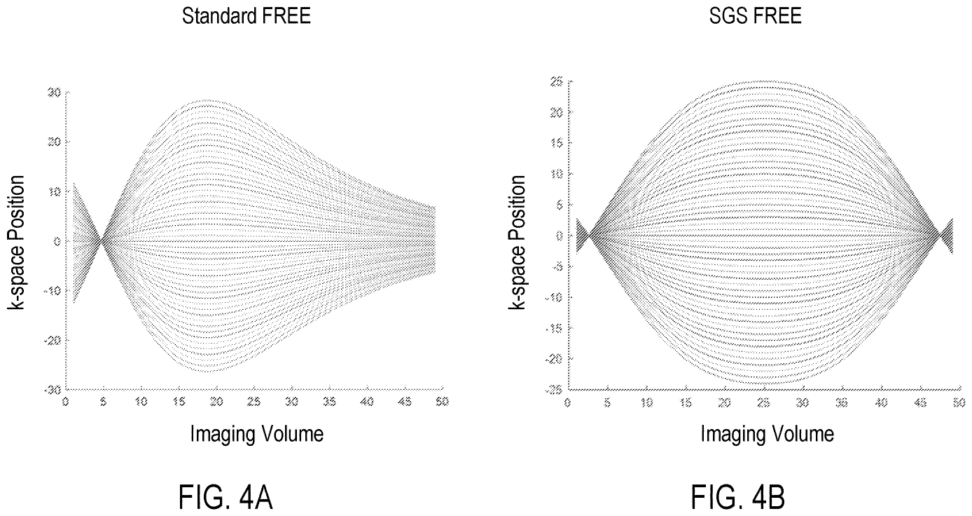

FIGS. 4A and 4B show example 1D k-space trajectories for coil setups similar to those shown in FIGS. 1B and 2B. In particular, the k-space trajectory was simulated using Biot-Savart simulations. Standard FREE techniques were used with a single saddle coil to achieve the k-space trajectory shown in FIG. 4A. In contrast, SGS-FREE methods were used with two saddle coils separated along the encoded dimension, which produced the k-space trajectory shown in FIG. 4B. SGS-FREE achieves more consistent resolution and field of view over the imaging volume, which is especially apparent at higher k-space values. In this example, at the 20^{th} k-space line, the consistency of the FOV was improved by 44% by SGS-FREE as compared to standard FREE.

Here, a new imaging method, which promotes the complete removal of B₀ gradient coils in an MRI system, particularly targeting the phase-encoding gradients, has been described. In some implementations, an SGS-FREE sequence can be implemented with t a multi-shot double spin-echo imaging readout or another pulse sequence. In some other implementations, the SGS-FREE technique can utilize the adiabatic condition to be highly immune to nonuniformity of B₀. This resilience is present up to the bandwidth of the pulse. If greater resistance to inhomogeneity is needed, the pulse's BW can be increased, making SGS-FREE extremely robust to the expected B₀ inhomogeneity in lower-cost systems.

Previous RFI approaches fall short in the presence of large resonance offset. With conventional (constant frequency) pulses, resonance offset has the effect of tilting B_{eff} out of the transverse plane and, as a result, the ability to effectively rotate magnetization diminishes as the pulse duration increases.

In practice, several parameters of the SGS-FREE method can be modified to achieve a desired or target RF field gradient or phase pattern over a defined imaging volume. For example, modifying the number and position of RF coils or RF coil arrays, the amplitude modulation and phase or frequency modulation variables of the FM RF pulses (e.g., 204 and 206) for each channel in the RF coil arrays, and the pulse duration and bandwidth of each FM RF pulse (e.g., 204 and 206), etc. will affect the resulting phase accrual over the given imaging volume. In some cases, a target phase pattern may be defined, and an optimization or other design process may be performed to determine the optimal sequence and setup parameters. As an example, the target RF field gradient or phase pattern can be defined as a linear field along any direction with a range of slopes. The maximum of such slopes can be defined by the desired spatial resolution (e.g., k_{x,max} and k_{y,max}), and the step size of such slopes can be defined based on the desired imaging field of view (e.g., Δkₓ and Δk_{y}). Constrained machine learning (ML) or any number of optimization techniques can be used to minimize RF gradient error and reward homogeneous gradient sets.

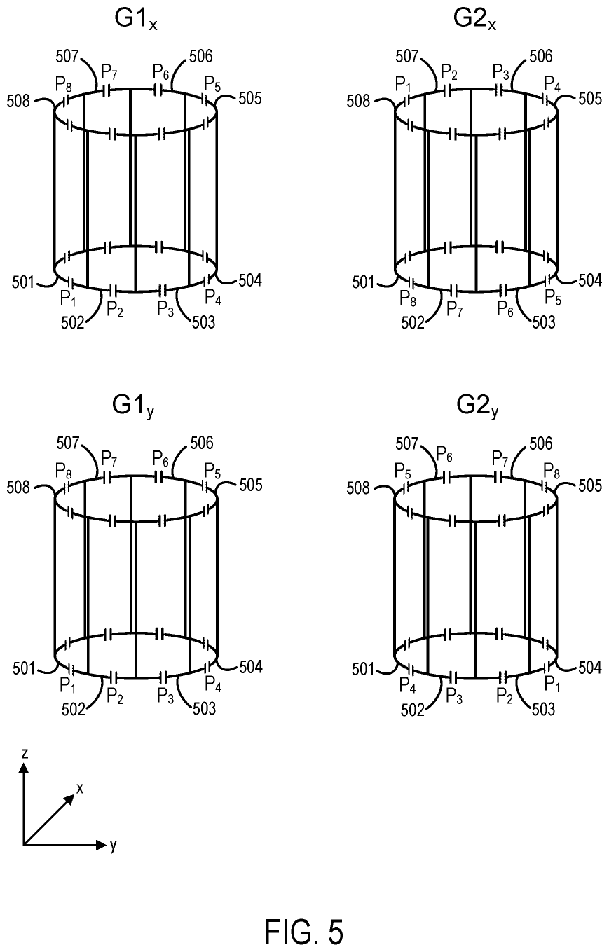

Another non-limiting example is shown in FIG. 5, which provides an example coil array setup. The coil array in FIG. 5 can be used to produce a 2D phase pattern while driving the coil in parallel transmit mode. For example, the pTx coil array may be an 8-channel birdcage coil or degenerated birdcage, as shown, or may be any one of many other coil array types, such as an array of surface coils, with varying number of channels. The single array can be used to provide several gradient sets, such as G1ₓ, G2ₓ, G1_{y}, and G2_{y} by adjusting the amplitude or phase parameters of the RF pulses applied by each coil element. In this way, each RF gradient set can include a specific subset of coil elements to uniquely define each RF gradient set from the same coils of the coil array.

For example, RF gradient set G1ₓ may include channel 1 501 applying RF pulse 1 (P₁), channel 2 502 applying RF pulse 2 (P₂), channel 3 503 applying RF pulse 3 (P₃), and so on, as shown. Next, to achieve G2ₓ, channel 1 501 can apply RF pulse 8 (P₈), channel 2 502 can apply RF pulse 7 (P₇), channel 3 503 can apply RF pulse 6 (P₆), and so on, to produce a different phase pattern in the x direction, which will superimpose with that achieved by G1ₓ. Similarly, in y, G1_{y} may include channel 1 501 applying RF pulse 1 (P₁), channel 2 502 applying RF pulse 2 (P₂), channel 3 503 applying RF pulse 3 (P₃), and so on, as shown. G2_{y} may include channel 1 501 applying RF pulse 4 (P₄), channel 2 502 applying RF pulse 3 (P₃), channel 3 503 applying RF pulse 2 (P₂), at so on, as shown in FIG. 5.

As another non-limiting example, the pulses applied by each gradient set may be unique pulses with a wide range of amplitude and phase modulating parameters. They may also have differing pulse durations or may even be different types of pulses, if desired. Additionally or alternatively, the gradient sets may include subsets of coil elements that do not include all of the same coil elements. For example, G1ₓ may be defined by channels 1-4 (501, 502, 503, and 504), while G2ₓ may be defined by channels 5-8 (505, 506, 507, and 508).

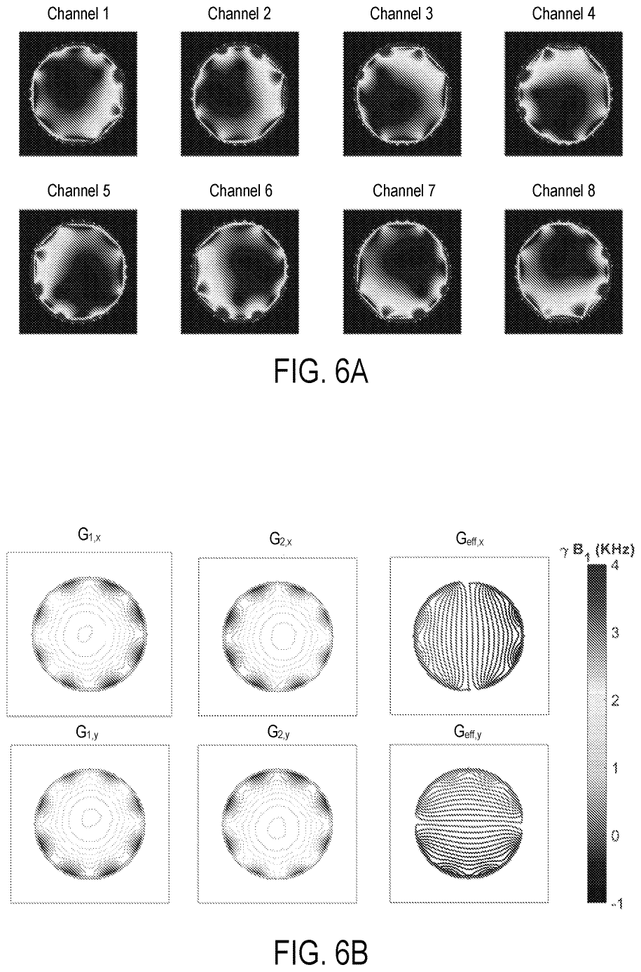

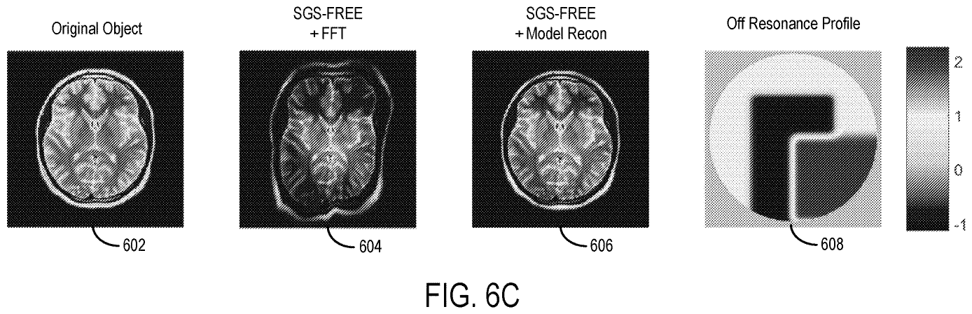

Referring now to FIGS. 6A, 6B, and 6C, SGS-FREE was tested using simulations of a well-tuned and matched 8-channel degenerated birdcage (dBC) parallel transmit RF coil with a diameter of 25 cm and height of 10 cm loaded with a Duke head model. A field of view was defined as a 23 cm circle. The normalized magnitude of the Bit profile for the 8-channel dBC coil is shown for a center slice in FIG. 6A.

The Larmor frequency was set to 64 Hz, corresponding to Hydrogen protons at 1.5 T. The 8-channel RF array was used to define four gradient sets (i.e., G1ₓ, G2ₓ, G1_{y}, and G2_{y}). In this non-limiting example, the gradient sets share the same 8 coils of the 8-channel RF array. However, the distinct gradient sets are distinguished based on the amplitude and phase modulation variables that correspond to the four pulses (i.e., R_{x,a,G1}, R_{x,b,G2}, R_{y,a,G1}, and R_{y,b,G2}). Constrained optimization was implemented to iteratively determine amplitude modulation variables and phase modulation variables, to generate target linear RF field gradients over the defined imaging volume. The optimization process may be performed using machine learning or other optimization techniques. The loss function was designed to minimize RF gradient error while rewarding homogeneous gradient sets. 32 amplitude and 32 phase modulation variables (8 channels×4 gradient sets, each) were iteratively found to define the four gradient sets used to encode the x and y dimensions for a total of 64 optimization parameters.

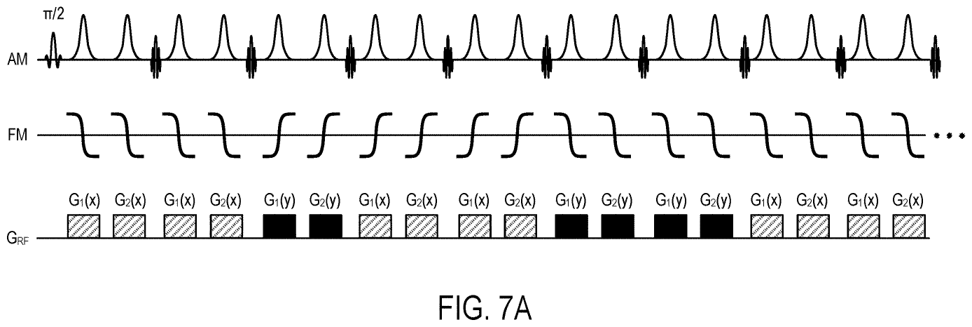

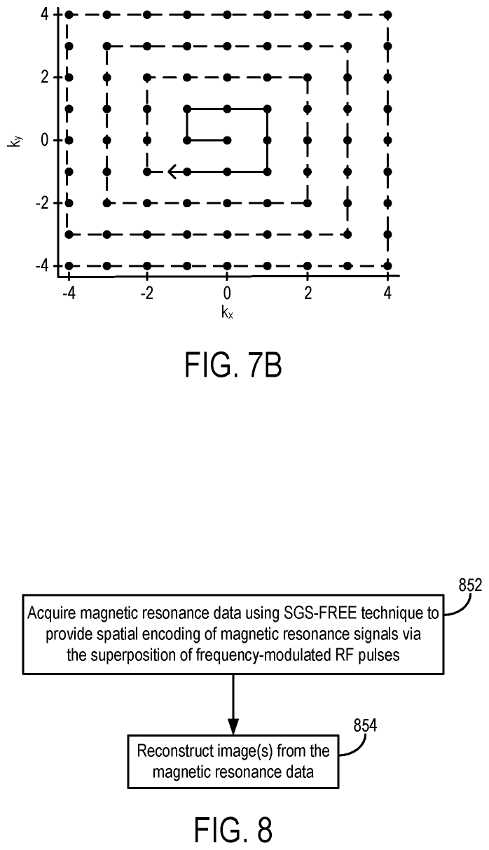

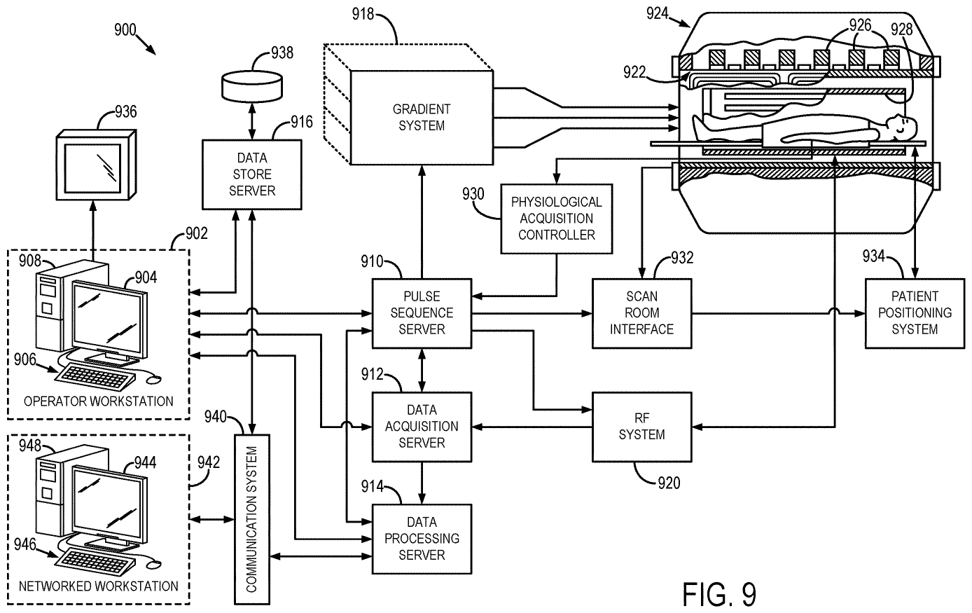

The optimized gradient sets (G1ₓ, G2ₓ, G1_{y}, ad G2_{y}) are shown in FIG. 6B. The simulations account for coupling between the rungs and the Duke head model at 64 MHz, which creates asymmetries. The sequential use of G1ₓ and G2ₓ achieves an effective gradient (G_{eff,x}) that varies approximately linearly along x. Similarly, the sequential use of G1_{y} and G2_{y} achieves an effective gradient (G_{eff,y}) that varies approximately linearly along y. Such linear gradients may be used to sample cartesian k-space, as demonstrated in FIG. 7B below, for example.

In general, k-space can be sampled by measuring the signal formed by the echoes (e.g., even echoes, odd echoes, or both). In some implementations, k-space can be filled by measuring the even echoes only. Because the quadratic phase in the chemical shift dimension is refocused in the even echoes, it may be advantageous to only sample the even echoes. However, in some implementations, the odd echoes can be measured. For example, if the chemical shift is sufficiently small over a pixel, the odd echoes can provide sufficient signal. Such signal may be reduced based on dephasing caused by chemical shift, but the signal loss may be small as the quadratic phase is typically slowly varying. In some implementations, the DC phase of the odd echoes can be measured or estimated and corrected in post processing. Thus, k-space can be filled by measuring even echoes only, odd echoes only, all echoes, or some combination of the even and odd echoes.

Referring to FIG. 6C, a Duke head phantom 602 was used to simulate imaging with SGS-FREE in the presence of a simulated large off-resonance 608. SGS-FREE was simulated using propagator analysis through 128×128 cartesian points to sample k-space. The images were reconstructed from the simulated data using the standard inverse Fourier transform 604 or a model-based reconstruction 606, which will be described in further detail below. As FIG. 6C shows, 2D SGS-FREE with a model-based reconstruction can achieve high quality images (e.g., 606) even in the presence of large off resonance (e.g., 608).

While the use of the superposition of phase accrual from multiple gradient sets greatly reduces the non-linearity of the net phase, the resulting phase gradient is generally not exactly linear, especially near the edges of the FOV, as seen in FIG. 2B. However, the non-linearities in the RF coils' B₁ maps dominated the distortions seen in SGS-FREE's reconstruction, stretching and compressing the reconstruction towards the nonlinear regions of the coil. The effects that SGS-FREE has on spins are equivalent to standard MRI phase encoding, so many of the approaches available to standard MRI for distortion-correction, parameter optimization, or post-processing can be reasonably applied here to tackle the fractional pixel distortion seen at lower B₁ values. One condition to improve reconstructions, as shown experimentally and in simulations, was to utilize SGS-FREE with higher B₁ values and linear coil maps. An additional benefit of SGS-FREE is that the field-of-view (“FOV”) is defined from the beginning of the coil's field, as opposed to set by the gradients. In applications where the RF coil can be attached to the subject, SGS-FREE could lead to a higher resistance to motion artifacts, as the FOV moves with the coil.

In some of the examples described in the present disclosure, SGS-FREE was implemented by holding the BW of the pulses constant and increasing or decreasing the length of the pulses. By using the superposition of two B₁ gradients with two AFPs, the net magnetization phase pattern can then encode spatial information. Other RFIs do not utilize FM pulses, and with solely AM pulses, increasing or decreasing the length of the pulse changes the BW of the pulse. This has the effect of phase-encoding variable ranges of isochromats. When utilizing SGS-FREE, holding the BW constant enabled the phase-encoding of the same range of isochromats.

The systems and methods described in the present disclosure make use of FM functions and an approximately linearly varying B₁ map. The SGS-FREE sequence, coil assemblies, and experimental results described in the present disclosure are non-limiting examples. SGS-FREE does not limit the FM function to HS1 pulses and can be applied using other AFP pulses, such as HS8 pulses. In addition, it is contemplated that SGS-FREE is compatible with other pulses not yet investigated that may carry their own benefits (e.g., chirp). Moreover, in some implementations, constant frequency RF pulses may be used, such as composite RF pulses or amplitude modulated pulses. While such pulses may not be as insensitive to B₀ inhomogeneity as the use of AFP pulses, they can still provide spatial encoding with relaxed hardware requirements. B₀ inhomogeneity may be corrected during signal post-processing methods.

The example sequence described above is a multi-shot approach, whereby one point of k-space is acquired per shot; however, more complex SGS-FREE sequences can be developed, such as ones that utilize spin-echo trains to acquire all of k-space in one shot or more complex k-space trajectories. For example, a 2D SGS-FREE multi-echo pulse sequence is shown in FIG. 7A. After an initial π/2 excitation pulse, a train of adiabatic full-passage pulses may be applied. The sequential gradient sets may be played along the G_{RF} axis to alternatingly achieve linear spatial encoding along x and y. In some implementations, k-space can be filled by acquiring data during all echoes, only the even echoes, only the odd echoes, or some combination of odd and even echoes. For example, k-space may be filled according to the pattern shown in FIG. 7B or in another way. As a non-limiting example, the RF pulses may be HS3 AFP pulses having a BW of 5 kHz and pulse duration of 2.5 ms that may achieve adiabaticity throughout the brain region with a peak γB₁/2π between 1.5-2.3 kHz.

Referring now to FIG. 8, a flowchart is illustrated as setting forth the steps of an example method for magnetic resonance imaging a subject using an SGS-FREE technique to acquire data from the subject. As described above in more detail, in an SGS-FREE technique data are acquired using at least two gradient sets that produce a superposition of B₁ RF fields to create a phase pattern that provides spatial encoding (e.g., phase encoding) of magnetic resonance signals. In this way, the SGS-FREE technique allows for magnetic resonance data to be acquired from a subject without the need for magnetic field gradient coils.

The method includes acquiring magnetic resonance data from a subject using an SGS-FREE technique, as indicated at block 852. In some implementations, block 852 may include determining pulse sequence parameters of each pulse and gradient set (e.g., frequency or phase modulation variables, amplitude modulation variables, time bandwidth product, pulse type, time-bandwidth produce, pulse duration, bandwidth, and so forth). Such parameters may be chosen to achieve a desired k-space trajectory or spatial encoding. As described above, the magnetic resonance data can be generally acquired using an SGS-FREE technique, in which spatial encoding of magnetic resonance signals is provided, at least partially, by the superposition of B₁ RF fields produced by at least two gradient sets, as opposed to establishing magnetic field gradients (e.g., gradients in the main magnetic field) by use of magnetic field gradient coils.

After the magnetic resonance data are acquired, one or more images are reconstructed from the data, as indicated at block 854. In some embodiments, a Fourier transform-based image reconstruction can be used to reconstruct images from the magnetic resonance data, similar to conventional reconstruction techniques. In other embodiments, other reconstruction techniques can be used, including parallel image reconstruction techniques, iterative reconstruction techniques, machine learning-based imaged reconstruction techniques, and so on.

As one non-limiting example, a model-based image reconstruction technique can be used to reconstruct images acquired using an SGS-FREE technique. For instance, an iterative first-order proximal gradient method can be used to solve a regularized linear inverse problem that is based on a model of the SGS-FREE encoding technique. As an example, the following regularized linear inverse problem can be solved:

$${‖ Ax - y ‖}_{2}^{2} + λ Ω ( x ) ;$$

where A represents the encoding matrix, which can be determined via full Bloch simulation with known field inhomogeneities and receive coil sensitivities. For instance, as a non-limiting example, to generate the encoding matrix, the Bloch equations can be simulated using a 2D parallelized Bloch simulator. The simulation can be run with a sub-voxel averaging factor (e.g., a sub-voxel averaging factor of 8) along both dimensions to mimic a continuous object. With the encoding matrix generated, the receive coil sensitivity profiles can be incorporated into the model by constructing a matrix out of the coil sensitivities as each coil sees the same encoding. This approach can be readily extended to multiple receive coils and used to reconstruct images from undersampled data, or other data acquired using accelerating data acquisition techniques. Advantageously, using a model-based image reconstruction allows for more variation in how SGS-FREE encoding can be implemented. For example, when using a model-based image reconstruction B₁ coils with nonlinear gradients can be used, since the nonlinear B₁ field's distortions can be appropriately corrected for using the model-based image reconstruction.

Referring again to FIG. 6C, in an experimental simulation based on the Duke head phantom 602, the model-based reconstruction reduced distortions caused by residual non-linearities of the net phase. When using the standard fast Fourier transform reconstruction 604, the residual spatial distortion is apparent. However, the model-based reconstruction 606 produces a simulated image of similar quality as the ideal image of the Duke head phantom 602.

Referring particularly now to FIG. 7, an example of a magnetic resonance imaging (“MRI”) system 700 that can implement the methods described here is illustrated. The MRI system 700 includes an operator workstation 702 that may include a display 704, one or more input devices 706 (e.g., a keyboard, a mouse), and a processor 708. The processor 708 may include a commercially available programmable machine running a commercially available operating system. The operator workstation 702 provides an operator interface that facilitates entering scan parameters into the MRI system 700. The operator workstation 702 may be coupled to different servers, including, for example, a pulse sequence server 710, a data acquisition server 712, a data processing server 714, and a data store server 716. The operator workstation 702 and the servers 710, 712, 714, and 716 may be connected via a communication system 740, which may include wired or wireless network connections.

The pulse sequence server 710 functions in response to instructions provided by the operator workstation 702 to operate a radiofrequency (“RF”) system 720, and optionally a gradient system 718. In some configurations, the MRI system 700 may not include a gradient system 718 and instead spatial encoding can be provided by using the SGS-FREE techniques described in the present disclosure to generate B₁ gradients with the RF system 720. When the gradient system 718 is present and implemented for partial spatial encoding (e.g., slice encoding), gradient waveforms for performing a prescribed scan are produced and applied to the gradient system 718, which then excites gradient coils in an assembly 722 to produce the magnetic field gradients that are used for spatially encoding magnetic resonance signals along spatial dimensions otherwise not encoded using the SGS-FREE techniques described in the present disclosure. In these configurations, the gradient coil assembly 722 can form part of a magnet assembly 724 that includes a polarizing magnet 726 and a whole-body RF coil 728.

RF waveforms are applied by the RF system 720 to the RF coil 728, or a separate local coil to perform the prescribed magnetic resonance pulse sequence. Responsive magnetic resonance signals detected by the RF coil 728, or a separate local coil, are received by the RF system 720. The responsive magnetic resonance signals may be amplified, demodulated, filtered, and digitized under direction of commands produced by the pulse sequence server 710. The RF system 720 includes an RF transmitter for producing a wide variety of RF pulses used in MRI pulse sequences. The RF transmitter is responsive to the prescribed scan and direction from the pulse sequence server 710 to produce RF pulses of the desired frequency, phase, and pulse amplitude waveform. The generated RF pulses may be applied to the whole-body RF coil 728 or to one or more local coils or coil arrays.

The RF system 720 also includes one or more RF receiver channels. An RF receiver channel includes an RF preamplifier that amplifies the magnetic resonance signal received by the coil 728 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

M=\sqrt{I²+Q²}
and the phase of the received magnetic resonance signal may also be determined according to the following relationship:

$$φ = {tan}^{- 1} ( \frac{Q}{I} ) .$$

The pulse sequence server 710 may receive patient data from a physiological acquisition controller 730. By way of example, the physiological acquisition controller 730 may receive signals from a number of different sensors connected to the patient, including electrocardiograph (“ECG”) signals from electrodes, or respiratory signals from a respiratory bellows or other respiratory monitoring devices. These signals may be used by the pulse sequence server 710 to synchronize, or “gate,” the performance of the scan with the subject's heart beat or respiration.

The pulse sequence server 710 may also connect to a scan room interface circuit 732 that receives signals from various sensors associated with the condition of the patient and the magnet system. Through the scan room interface circuit 732, a patient positioning system 734 can receive commands to move the patient to desired positions during the scan.

The digitized magnetic resonance signal samples produced by the RF system 720 are received by the data acquisition server 712. The data acquisition server 712 operates in response to instructions downloaded from the operator workstation 702 to receive the real-time magnetic resonance data and provide buffer storage, so that data is not lost by data overrun. In some scans, the data acquisition server 712 passes the acquired magnetic resonance data to the data processor server 714. In scans that require information derived from acquired magnetic resonance data to control the further performance of the scan, the data acquisition server 712 may be programmed to produce such information and convey it to the pulse sequence server 710.

The data processing server 714 receives magnetic resonance data from the data acquisition server 712 and processes the magnetic resonance data in accordance with instructions provided by the operator workstation 702. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 714 are conveyed back to the operator workstation 702 for storage. Real-time images may be stored in a data base memory cache, from which they may be output to operator display 702 or a display 736. Batch mode images or selected real time images may be stored in a host database on disc storage 738. When such images have been reconstructed and transferred to storage, the data processing server 714 may notify the data store server 716 on the operator workstation 702. The operator workstation 702 may be used by an operator to archive the images, produce films, or send the images via a network to other facilities.

The MRI system 700 may also include one or more networked workstations 742. For example, a networked workstation 742 may include a display 744, one or more input devices 746 (e.g., a keyboard, a mouse), and a processor 748. The networked workstation 742 may be located within the same facility as the operator workstation 702, or in a different facility, such as a different healthcare institution or clinic.

The networked workstation 742 may gain remote access to the data processing server 714 or data store server 716 via the communication system 740. Accordingly, multiple networked workstations 742 may have access to the data processing server 714 and the data store server 716. In this manner, magnetic resonance data, reconstructed images, or other data may be exchanged between the data processing server 714 or the data store server 716 and the networked workstations 742, such that the data or images may be remotely processed by a networked workstation 742.

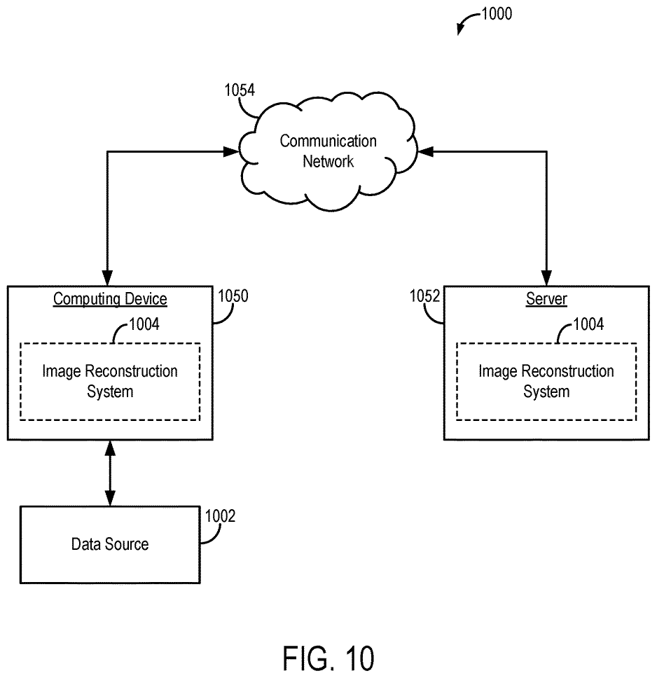

Referring now to FIG. 10, an example of a system 1000 for reconstructing images from data acquired using an SGS-FREE technique using an image reconstruction, which in some instances may be a model-based image reconstruction framework, in accordance with some embodiments of the systems and methods described in the present disclosure is shown. As shown in FIG. 10, a computing device 1050 can receive one or more types of data (e.g., k-space data, receiver coil sensitivity data) from data source 1002. In some embodiments, computing device 1050 can execute at least a portion of an image reconstruction system 1004 to reconstruct images from magnetic resonance data (e.g., k-space data) acquired using an SGS-FREE technique. In some embodiments, the image reconstruction system 1004 can implement a model-based image reconstruction, as described above.

Additionally or alternatively, in some embodiments, the computing device 1050 can communicate information about data received from the data source 1002 to a server 1052 over a communication network 1054, which can execute at least a portion of the image reconstruction system 1004. In such embodiments, the server 1052 can return information to the computing device 1050 (and/or any other suitable computing device) indicative of an output of the image reconstruction system 1004.

In some embodiments, computing device 1050 and/or server 1052 can be any suitable computing device or combination of devices, such as a desktop computer, a laptop computer, a smartphone, a tablet computer, a wearable computer, a server computer, a virtual machine being executed by a physical computing device, and so on. The computing device 1050 and/or server 1052 can also reconstruct images from the data.

In some embodiments, data source 1002 can be any suitable source of data (e.g., measurement data, images reconstructed from measurement data, processed image data), such as an MRI system, another computing device (e.g., a server storing measurement data, images reconstructed from measurement data, processed image data), and so on. In some embodiments, data source 1002 can be local to computing device 1050. For example, data source 1002 can be incorporated with computing device 1050 (e.g., computing device 1050 can be configured as part of a device for measuring, recording, estimating, acquiring, or otherwise collecting or storing data). As another example, data source 1002 can be connected to computing device 1050 by a cable, a direct wireless link, and so on. Additionally or alternatively, in some embodiments, data source 1002 can be located locally and/or remotely from computing device 1050, and can communicate data to computing device 1050 (and/or server 1052) via a communication network (e.g., communication network 1054).

In some embodiments, communication network 1054 can be any suitable communication network or combination of communication networks. For example, communication network 1054 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 1054 can be a local area network, a wide area network, a public network (e.g., the Internet), a private or semi-private network (e.g., a corporate or university intranet), any other suitable type of network, or any suitable combination of networks. Communications links shown in FIG. 10 can each be any suitable communications link or combination of communications links, such as wired links, fiber optic links, Wi-Fi links, Bluetooth links, cellular links, and so on.

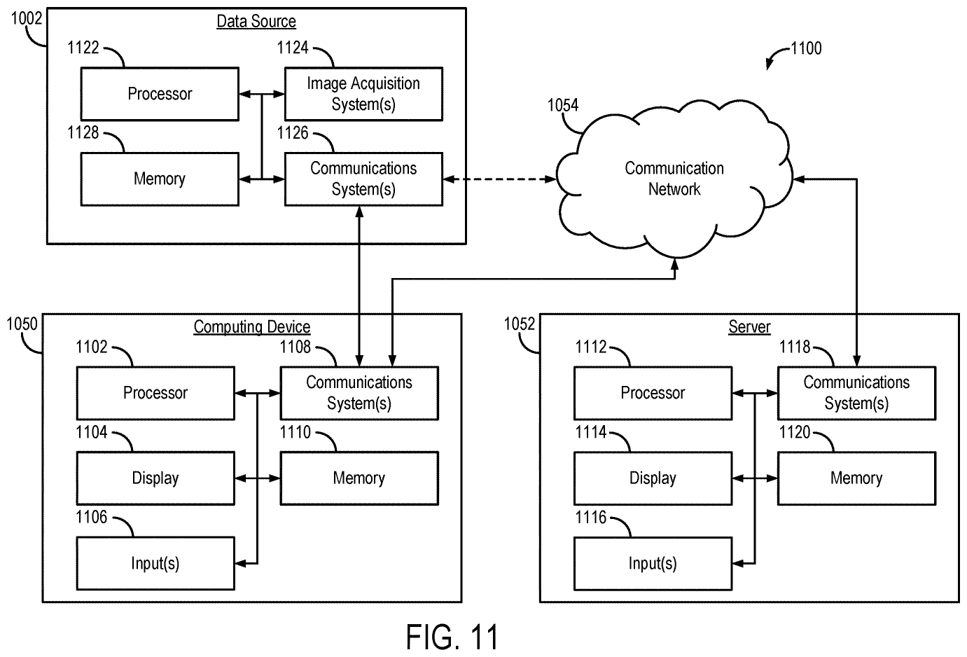

Referring now to FIG. 11, an example of hardware 1100 that can be used to implement data source 1002, computing device 1050, and server 1052 in accordance with some embodiments of the systems and methods described in the present disclosure is shown. As shown in FIG. 11, in some embodiments, computing device 1050 can include a processor 1102, a display 1104, one or more inputs 1106, one or more communication systems 1108, and/or memory 1110. In some embodiments, processor 1102 can be any suitable hardware processor or combination of processors, such as a central processing unit (“CPU”), a graphics processing unit (“GPU”), and so on. In some embodiments, display 1104 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 1106 can include any suitable input devices and/or sensors that can be used to receive user input, such as a keyboard, a mouse, a touchscreen, a microphone, and so on.

In some embodiments, communications systems 1108 can include any suitable hardware, firmware, and/or software for communicating information over communication network 1054 and/or any other suitable communication networks. For example, communications systems 1108 can include one or more transceivers, one or more communication chips and/or chip sets, and so on. In a more particular example, communications systems 1108 can include hardware, firmware, and/or software that can be used to establish a Wi-Fi connection, a Bluetooth connection, a cellular connection, an Ethernet connection, and so on.

In some embodiments, memory 1110 can include any suitable storage device or devices that can be used to store instructions, values, data, or the like, that can be used, for example, by processor 1102 to present content using display 1104, to communicate with server 1052 via communications system(s) 1108, and so on. Memory 1110 can include any suitable volatile memory, non-volatile memory, storage, or any suitable combination thereof. For example, memory 1110 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 1110 can have encoded thereon, or otherwise stored therein, a computer program for controlling operation of computing device 1050. In such embodiments, processor 1102 can execute at least a portion of the computer program to present content (e.g., images, user interfaces, graphics, tables), receive content from server 1052, transmit information to server 1052, and so on. For example, the processor 1102 and the memory 1110 can be configured to perform the methods described herein.

In some embodiments, server 1052 can include a processor 1112, a display 1114, one or more inputs 1116, one or more communications systems 1118, and/or memory 1120. In some embodiments, processor 1112 can be any suitable hardware processor or combination of processors, such as a CPU, a GPU, and so on. In some embodiments, display 1114 can include any suitable display devices, such as an LCD screen, LED display, OLED display, electrophoretic display, a computer monitor, a touchscreen, a television, and so on. In some embodiments, inputs 1116 can include any suitable input devices and/or sensors that can be used to receive user input, such as a keyboard, a mouse, a touchscreen, a microphone, and so on.

In some embodiments, communications systems 1118 can include any suitable hardware, firmware, and/or software for communicating information over communication network 1054 and/or any other suitable communication networks. For example, communications systems 1118 can include one or more transceivers, one or more communication chips and/or chip sets, and so on. In a more particular example, communications systems 1118 can include hardware, firmware, and/or software that can be used to establish a Wi-Fi connection, a Bluetooth connection, a cellular connection, an Ethernet connection, and so on.

In some embodiments, memory 1120 can include any suitable storage device or devices that can be used to store instructions, values, data, or the like, that can be used, for example, by processor 1112 to present content using display 1114, to communicate with one or more computing devices 1050, and so on. Memory 1120 can include any suitable volatile memory, non-volatile memory, storage, or any suitable combination thereof. For example, memory 1120 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 1120 can have encoded thereon a server program for controlling operation of server 1052. In such embodiments, processor 1112 can execute at least a portion of the server program to transmit information and/or content (e.g., data, images, a user interface) to one or more computing devices 1050, receive information and/or content from one or more computing devices 1050, receive instructions from one or more devices (e.g., a personal computer, a laptop computer, a tablet computer, a smartphone), and so on.

In some embodiments, the server 1052 is configured to perform the methods described in the present disclosure. For example, the processor 1112 and memory 1120 can be configured to perform the methods described herein.

In some embodiments, data source 1002 can include a processor 1122, one or more data acquisition systems 1124, one or more communications systems 1126, and/or memory 1128. In some embodiments, processor 1122 can be any suitable hardware processor or combination of processors, such as a CPU, a GPU, and so on. In some embodiments, the one or more data acquisition systems 1124 are generally configured to acquire data, images, or both, and can include an MRI system. Additionally or alternatively, in some embodiments, the one or more data acquisition systems 1124 can include any suitable hardware, firmware, and/or software for coupling to and/or controlling operations of an MRI system. In some embodiments, one or more portions of the data acquisition system(s) 1124 can be removable and/or replaceable.

Note that, although not shown, data source 1002 can include any suitable inputs and/or outputs. For example, data source 1002 can include input devices and/or sensors that can be used to receive user input, such as a keyboard, a mouse, a touchscreen, a microphone, a trackpad, a trackball, and so on. As another example, data source 1002 can include any suitable display devices, such as an LCD screen, an LED display, an OLED display, an electrophoretic display, a computer monitor, a touchscreen, a television, etc., one or more speakers, and so on.

In some embodiments, communications systems 1126 can include any suitable hardware, firmware, and/or software for communicating information to computing device 1050 (and, in some embodiments, over communication network 1054 and/or any other suitable communication networks). For example, communications systems 1126 can include one or more transceivers, one or more communication chips and/or chip sets, and so on. In a more particular example, communications systems 1126 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 1128 can include any suitable storage device or devices that can be used to store instructions, values, data, or the like, that can be used, for example, by processor 1122 to control the one or more data acquisition systems 1124, and/or receive data from the one or more data acquisition systems 1124; to generate images from data; present content (e.g., data, images, a user interface) using a display; communicate with one or more computing devices 1050; and so on. Memory 1128 can include any suitable volatile memory, non-volatile memory, storage, or any suitable combination thereof. For example, memory 1128 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 1128 can have encoded thereon, or otherwise stored therein, a program for controlling operation of medical image data source 1002. In such embodiments, processor 1122 can execute at least a portion of the program to generate images, transmit information and/or content (e.g., data, images, a user interface) to one or more computing devices 1050, receive information and/or content from one or more computing devices 1050, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As used herein in the context of computer implementation, unless otherwise specified or limited, the terms “component,” “system,” “module,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

The present disclosure has described one or more preferred embodiments, and it should be appreciated that many equivalents, alternatives, variations, and modifications, aside from those expressly stated, are possible and within the scope of the invention.

1. A method for spatially encoding magnetic resonance signals during magnetic resonance imaging (MRI), the method comprising:
generating at least a first radiofrequency (RF)-induced phase pattern by applying a first RF pulse using a first RF gradient set of an RF coil assembly of an MRI system and a second RF-induced phase pattern by applying a second RF pulse using a second RF gradient set of the RF coil assembly of the MRI system;
wherein a superposition of the first RF-induced phase pattern and the second RF-induced phase pattern generates a phase pattern that spatially encodes magnetic resonance signals generated with the MRI system.

2. The method of claim 1, wherein the first RF pulse produces a first B1 field such that the first RF-induced phase pattern is dependent on the first B1 field, and the second RF pulse produces a second B1 field such that the second RF-induced phase pattern is dependent on the second B1 field.

3. The method of claim 1, wherein the first RF pulse is a frequency-modulated pulse, and the second RF pulse is a frequency-modulated pulse.

4. The method of claim 1, wherein the first RF pulse is at least one of a composite RF pulse or an amplitude modulated RF pulse.

5. The method of claim 1, wherein the RF coil assembly comprises a first pair of RF coils aligned along a first direction, wherein the first pair of RF coils comprises a first RF coil and a second RF coil, and wherein the first RF gradient set comprises the first RF coil and the second RF gradient set comprises the second RF coil.

6. The method of claim 5, wherein the RF coil assembly further comprises a second pair of RF coils aligned along a second direction that is different from the first direction, wherein the second pair of RF coils comprises a third RF coil and a fourth RF coil, and wherein a third RF gradient set comprises the third RF coil and a fourth RF gradient set comprises the fourth RF coil; wherein the method further comprises:
generating a second radiofrequency (RF)-induced phase pattern by applying a third RF pulse using the third RF gradient set of the RF coil assembly and a fourth RF-induced phase pattern by applying a fourth RF pulse using the fourth RF gradient set of the RF coil assembly;
wherein a superposition of the third RF-induced phase pattern and the fourth RF-induced phase pattern generates an additional phase pattern that spatially encodes magnetic resonance signals generated with the MRI system along the second direction.

7. The method of claim 1, wherein the RF coil assembly comprises an RF coil array having a plurality of RF coils, and wherein the first RF gradient set comprises a first subset of the plurality of RF coils in the RF coil array and the second RF gradient set comprises a second subset of the plurality of RF coils in the RF coil array.

8. The method of claim 7, wherein the first subset of the plurality of RF coils comprises different RF coils than the second subset of the plurality of RF coils.

9. The method of claim 8, wherein the first subset of the plurality of RF coils comprises at least some of the second subset of the plurality of RF coils.

10. The method of claim 1, wherein generating at least the first RF-induced phase pattern and the second RF-induced phase pattern comprises:
defining a target phase pattern; and
performing, by a processor, an optimization of radiofrequency parameters of at least a first frequency-modulated RF pulse generated by the first RF gradient set and a second frequency-modulated RF pulse generated by the second RF gradient set to maximally achieve the target phase pattern.

11. The method of claim 10, wherein the radiofrequency parameters include at least one of a spatial position of each gradient set, a number of radiofrequency coils within each gradient set, amplitude modulation parameters of the first and second RF pulses, phase modulation variables of the first and second RF pulses, and a time-bandwidth product of each RF pulse.

12. The method of claim 11, wherein the target phase pattern comprises a linear gradient along a direction.

13. The method of claim 1, further comprising:
generating an RF excitation pulse with the MRI system before generating the at least first RF-induced phase pattern and second RF-induced phase pattern;
acquiring magnetic resonance data with the MRI system by sampling magnetic resonance signals formed in response to the RF excitation pulse; and
reconstructing an image from the acquired magnetic resonance data.

14. A method for magnetic resonance imaging, the method comprising:
(a) acquiring magnetic resonance data from a subject using a magnetic resonance imaging (MRI) system by:
generating a pulse sequence with the MRI system, the pulse sequence comprising:
a radio frequency (RF) excitation pulse;
a first RF pulse generated by a first RF gradient set, wherein the first RF pulse is generated after the RF excitation pulse and produces an RF-induced phase pattern;
a second RF pulse generated by a second RF gradient set, wherein the second RF pulse is generated after the first RF pulse and produces an RF-induced phase pattern;
acquiring magnetic resonance data with the MRI system by sampling magnetic resonance signals formed in response to the RF excitation pulses, wherein a phase is imparted to magnetic resonance signals in response to the RF excitation pulses, wherein the value of the phase comprises a superposition of:
a first phase component whose value is dependent on the first RF gradient set; and
a second phase component whose value is dependent on the second RF gradient set;
(b) reconstructing an image from the acquired magnetic resonance data.

15. (canceled)

16. The method according to claim 3, wherein the first frequency-modulated RF pulse and the second frequency-modulated RF pulse comprise at least one of adiabatic full-passage RF pulses, hyperbolic secant (HS) RF pulses, or chirp RF pulses.

17. The method according to claim 1, wherein the first frequency-modulated RF pulse has a first time-bandwidth product and the second frequency-modulated RF pulse has a second time-bandwidth product, wherein at least one of the first time-bandwidth product or the second time-bandwidth product is changed at least one of in a subsequent repetition of the pulse sequence or within the pulse sequence by changing a pulse duration of the first frequency-modulated RF pulse or a pulse duration of the second frequency-modulated RF pulse while a bandwidth of the first frequency-modulated RF pulse and the second frequency-modulated RF pulse is held constant.

18. (canceled)

19. The method of claim 14, wherein the phase imparted to magnetic resonance signals is linear along an axis within at least some of an imaging field of view.

20. The method of claim 14, further comprising pulse design of the RF pulses to achieve a target superposition of phase, wherein the pulse design comprises:
(a) defining an imaging volume;
(b) defining a target superposition of phase;
(c) simulating a superposition of phase based on a spatial model of the first RF gradient set and the second RF gradient set and the amplitude and phase modulation variables of the RF pulses;
(d) defining a loss function based on the target superposition of phase and the simulated superposition of phase; and
(e) performing an optimization to minimize the loss function.

21. The method according to claim 10, wherein the optimization is further constrained by at least one of SAR requirements or adiabaticity requirements.

22. (canceled)

23. The method according to claim 10, wherein performing the optimization comprises at least one of constrained machine learning methods or reinforcement learning methods.

24. (canceled)

25. A method for magnetic resonance imaging, the method comprising:
(a) acquiring magnetic resonance data from a subject using a magnetic resonance imaging (MRI) system to generate a pulse sequence that generates a plurality of radio frequency (RF) gradients using a plurality of RF pulses, wherein a superposition of the RF gradients provides spatial encoding of the magnetic resonance data; and
(b) reconstructing an image from the acquired magnetic resonance data.

26. The method of claim 25, wherein the RF pulses produce a B1-dependent phase of the magnetic resonance data.

27. The method of claim 26, wherein the RF pulses are frequency-modulated RF pulses.

28. The method according to claim 13, wherein reconstructing the image from the acquired magnetic resonance data comprises using an iterative model-based image reconstruction that models spatial encoding based on a signal evolution simulation.

29. (canceled)

30. (canceled)

31. (canceled)

32. The method of claim 27, wherein the frequency-modulated RF pulses comprise at least one of adiabatic full passage RF pulses, hyperbolic secant RF pulses, or chirp RF pulses.

33. (canceled)

34. (canceled)
